(19) United States
(12) Patent Application Publication
(10) Pub. No.: US 2025/0192605 A1
(43) Pub. Date: Jun. 12, 2025

(54) SWITCHED REDUNDANT STATIC TRANSFER SWITCH RAPID TURN-OFF SYSTEM

(71) Applicant: ABB Schweiz AG, Baden (CH)

(72) Inventors: Hany Habib, Richmond, VA (US); Veerakumar Bose, Richmond, VA (US); Thomas Anthony Kendzia, III, Richmond, VA (US); Christopher Alan Belcastro, Richmond, VA (US)

(21) Appl. No.: 18/534,041

(22) Filed: Dec. 8, 2023

(51) Int. Cl. H02J 9/06

(52) U.S. Cl. CPC H02J 9/068; H02J 9/062

(57) ABSTRACT

Disclosed herein are a static transfer switch with redundant rapid turn-off (RTO) unit switching, and methods of operating the same. The static transfer switch includes a first switch between a first voltage source and a load, and a second switch between a second voltage source and the load, wherein the first switch and the second switch are configured to alternate power to the load between the first voltage source or the second voltage source. The static transfer switch also includes an RTO system coupled across the first and second switches. The RTO system includes a first RTO unit coupled in parallel with the first switch, a second RTO unit coupled in parallel with the second switch, and a first switched path connected between the first RTO unit and the second switch.

### FIELD OF THE DISCLOSURE

The present disclosure relates generally to static transfer switches. In particular, the present disclosure relates to static transfer switches including redundant rapid turn-off units.

### BACKGROUND

A static transfer switch (STS) is a device used to switch from a primary voltage source to an alternate voltage source, and vice versa, when the primary voltage source is unable to power a load. STSs are often implemented in mission critical environments, such as data centers, in which it is important that a back-up power source be available in case a primary power source is unavailable or degraded to a level unsuitable to power a load.

In at least some instances, an STS includes high-power solid-state switches, such as thyristors. The conventional thyristor is a passive turn-off switch, which requires the conduction current to naturally commutate below the thyristor's minimum holding current and reverse bias voltage to the anode of the thyristor, for a predefined duration of time, to achieve reliable turn-off and effect the switch in voltage sources. Some STSs incorporate rapid turn-off (RTO) units, which can force the zero-current turn-off condition and reduce the total time for the voltage source transfer. However, in the event of an RTO unit failure, these advantages may not be realized and, further, the STS may not function as intended, particularly where the STS includes only one RTO unit shared between two voltage sources.

### BRIEF DESCRIPTION

According to one aspect, a static transfer switch includes a first switch between a first voltage source and a load, and a second switch between a second voltage source and the load, wherein the first switch and the second switch are configured to alternate power to the load between the first voltage source or the second voltage source. The static transfer switch also includes an RTO system coupled across the first and second switches. The RTO system includes a first RTO unit coupled in parallel with the first switch, a second RTO unit coupled in parallel with the second switch, and a first switched path connected between the first RTO unit and the second switch.

In a further aspect, a method for redundant rapid turn-off (RTO) unit switching within a static transfer switch (STS) includes coupling a first switch between a first voltage source and a load, and coupling a second switch between a second voltage source and the load, wherein the first switch and the second switch are configured to alternate power to the load between the first voltage source or the second voltage source. The method also includes coupling an RTO system across the first and second switches, this coupling including coupling a first RTO unit in parallel with the first switch, coupling a second RTO unit in parallel with the second switch, and connecting a first switched path between the first RTO unit and the second switch. The method further includes activating the first RTO unit to force commutation of the second switch during a voltage source transfer from the second voltage source to the first voltage source.

The foregoing and other aspects, features, details, utilities, and advantages of the present disclosure will be apparent from reading the following description and claims, and from reviewing the accompanying drawings.

### BRIEF DESCRIPTION OF THE DRAWINGS

These and other features, aspects, and advantages of the present disclosure will become better understood when the following detailed description is read with reference to the accompanying drawings in which like characters represent like parts throughout the drawings, wherein:

FIG. 1 is a schematic diagram of a static transfer switch (STS) including a redundant rapid turn-off (RTO) system having multiple RTO units; and

FIG. 2 is a flow diagram of a method for RTO unit switching within an STS, such as the STS shown in FIG. 1.

Unless otherwise indicated, the drawings provided herein are meant to illustrate features of embodiments of this disclosure. These features are believed to be applicable in a wide variety of systems comprising one or more embodiments of this disclosure. As such, the drawings are not meant to include all conventional features known by those of ordinary skill in the art to be required for the practice of the embodiments disclosed herein.

### DETAILED DESCRIPTION OF THE DISCLOSURE

The present disclosure is directed a static transfer switch (STS) including a switched redundant rapid turn-off (RTO) system. The redundant RTO system includes two RTO units and two switches, and enables one RTO to interrupt current in the event of failure of the other RTO unit. This STS topology also enables current sharing between the two RTO units, increasing the maximum current that can be interrupted during start up or voltage source transfer without increasing the size or complexity of the individual RTO units.

In the following specification and the claims, reference will be made to a number of terms, which shall be defined to have the following meanings.

The singular forms “a”, “an”, and “the” include plural references unless the context clearly dictates otherwise.

“Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately”, and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

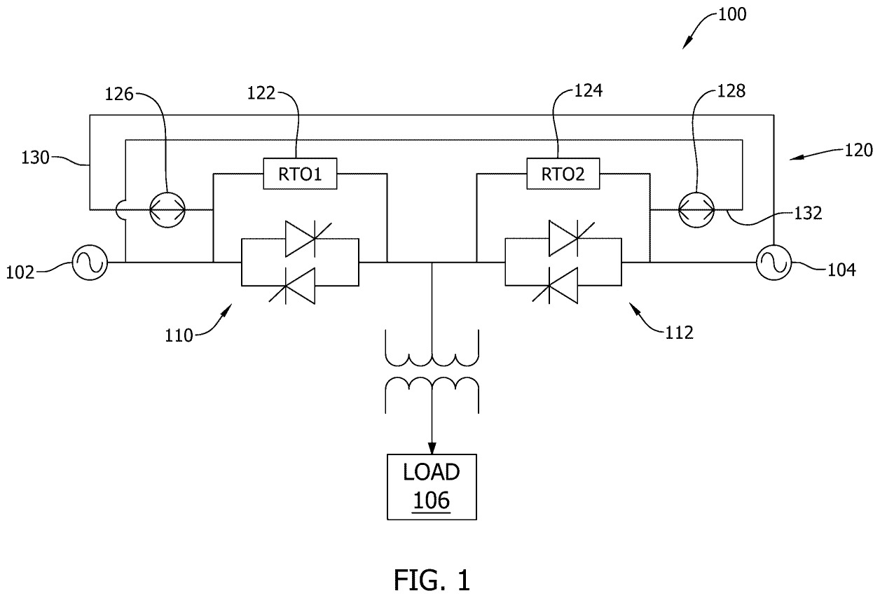

Turning now to the figures, FIG. 1 is a schematic diagram of a static transfer switch (STS) 100. STS 100 is used to switch from a first voltage source 102 to a second voltage source 104, and vice versa, to power a load 106. STS 100 includes a first switch 110, also referred to as a first SCR (silicon-controlled rectifier), coupled in series between first voltage source 102 and load 106. First SCR 110 includes, for example, a pair of thyristor switches. STS 100 also includes a second switch 112, also referred to as a second SCR, coupled in series between second voltage source 104 and load 106. Second SCR 112 includes, for example, a pair of thyristor switches. First SCR 110 and second SCR 112 are configured to alternate power to load 106 between first voltage source 102 or the second voltage source 104, respectively.

STS 100 further includes a rapid turn-off (RTO) system 120 coupled across SCRs 110, 112, which includes a first RTO unit 122 and a second RTO unit 124. STS 100 is activated during a load start-up process, or during a voltage source transfer between first voltage source 102 and second voltage source 104 powering load 106. As explained above, RTO units 122, 124 are configured to facilitate faster voltage source transfers. In particular, first RTO unit 122 coupled in parallel with first SCR 110 and is configured to force a zero-current condition across first SCR 110 during a voltage source transfer. Likewise, second RTO unit 124 is coupled in parallel with second SCR 112 and is configured to force a zero-current condition across second SCR 112 during a voltage source transfer. The specifics of RTO unit 122 and RTO unit 124 are not essential to the functionality of RTO system 120. Example RTO units are disclosed in U.S. Pat. Nos. 11,742,849, 11,258,296, 11,211,816, and 11,018,666, each of which are incorporated by reference herein.

RTO system 120 also includes a first switched path 130 connected between first RTO unit 122 and second SCR 112, as well a second switched path 132 connected between second RTO unit 124 and first SCR 110. First switched path 130 includes a first auxiliary switch 126, and second switched path 132 includes a second auxiliary switch 128. Auxiliary switch 126, 128 is any switching element, such as an electromechanical switch or, in alternative embodiments, a semiconductor switch (e.g., IGBT, MOSFET, etc.).

In accordance with the present disclosure, RTO system 120 enables activation of first RTO unit 122 to force a zero-current condition across second SCR 112, in the event of failure of second RTO unit 124 during the voltage source transfer. In particular, first auxiliary switch 126 is coupled between the series connection of second source 104 and second SCR 112 and the parallel connection of first SCR 110 and first RTO unit 122, via first switched path 130. In the event second RTO unit 124 fails, during a voltage source transfer, first auxiliary switch 126 is closed. Current conducts across first switched path 130, through first auxiliary switch 126 to first RTO unit 122, which forces the commutation of second SCR 112 to enable the voltage source transfer.

RTO system 120 also enables activation of second RTO unit 124 to force a zero-current condition across first SCR 110, in the event of failure of first RTO unit 122 during the voltage source transfer. In particular, second auxiliary switch 128 is coupled between the series connection of first source 102 and first SCR 110 and the parallel connection of second SCR 112 and second RTO unit 124, via second switched path 132. In the event first RTO unit 122 fails, during a voltage source transfer, second auxiliary switch 128 is closed. Current conducts across second switched path 132, through second auxiliary switch 128 to second RTO unit 124, which forces the commutation of first SCR 110 to enable the voltage source transfer.

This topology therefore enables switched activation of the alternative or other RTO unit—that is, an RTO unit not dedicated to a single SCR. The RTO capability is shared across multiple RTO units within RTO system 120, adding redundancy to ensure more reliable functionality of STS 100.

The topology of STS 100 as depicted in FIG. 1 also enables current sharing across RTO units 122, 124 during operation of either first voltage source 102 or second voltage source 104. Specifically, when auxiliary switches 126, 128 are both closed, concurrent operation and current sharing across RTO units 122, 124 is enabled. Moreover, because current sharing is enabled via paths 130, 132, RTO system 120 is capable of interrupting a higher magnitude of current, without requiring either RTO unit 122, 124 to increase in complexity, size, or current rating.

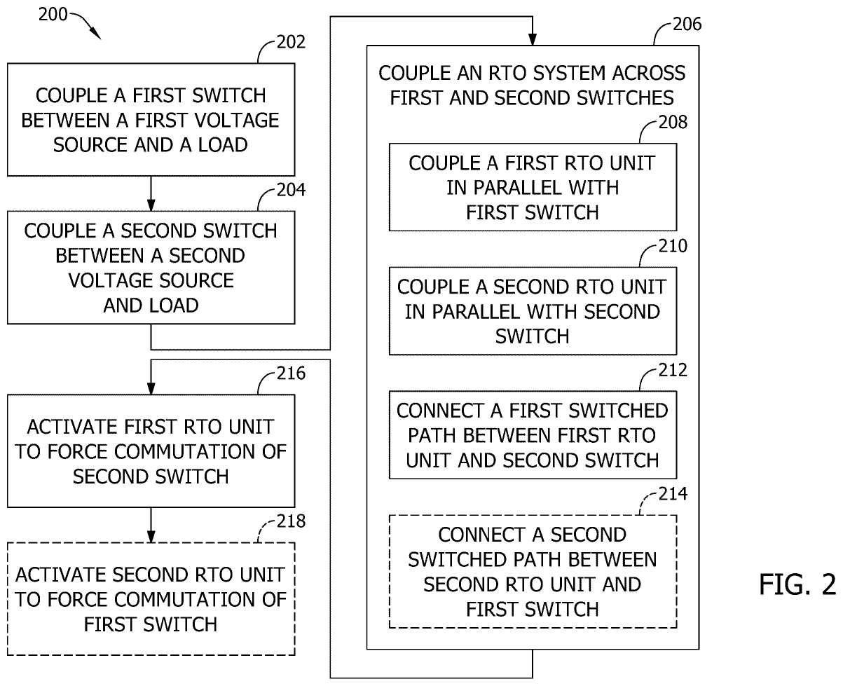

Turning to FIG. 2, a flow diagram of a method 200 of redundant RTO unit switching within an STS, such as STS 100 shown in FIG. 1, is depicted. Method 200 includes coupling 202 a first switch between a first voltage source and a load, and coupling 204 a second switch between a second voltage source and the load. The first switch and the second switch are configured to alternate power to the load between the first voltage source or the second voltage source.

Method 200 also includes coupling 206 an RTO system across the first and second switches. In one example embodiment, coupling 206 includes coupling 208 a first RTO unit in parallel with the first switch, coupling 210 a second RTO unit in parallel with the second switch, and connecting 212 a first switched path between the first RTO unit and the second switch. In some embodiments, coupling 206 also includes connecting 214 a second switched path between the second RTO unit and the first switch.

Method 200 further includes activating 216 the first RTO unit to force commutation of the second switch during a voltage source transfer from the second voltage source to the first voltage source. Activating 216 may include closing a first auxiliary switch along the first switched path. In some embodiments, method 200 also includes activating 218 the second RTO unit to force commutation of the first switch during a voltage source transfer from the first voltage source to the second voltage source. Activating 218 may include closing a second auxiliary switch along the second switched path.

In some embodiments, method 200 includes additional, fewer, or alternative steps. For example, where the first switched path includes a first auxiliary switch, and the second switched path includes a second auxiliary switch, method 200 may include closing the first and second auxiliary switches to enable current sharing between the first RTO unit and the second RTO unit while the first voltage source or the second voltage source is powering the load.

Method 200 is implemented, for example, using a control circuit or functional control layer on a PCB, which may include, for example, a microcontroller unit (MCU), a microprocessor, or any suitable processing and control component(s). The control circuit/layer may be implemented on the load (e.g., load 106, shown in FIG. 1) or in an intermediate control device within a system containing the load.

Example embodiments of the static transfer switch including the redundant RTO system, as well as methods of operating such a switch, are described in detail. The circuits and methods are not limited to the specific embodiments described herein, but rather, components of systems and/or steps of the methods may be utilized independently and separately from other components and/or steps described herein. For example, the method may also be used in combination with other components and are not limited to practice only with the circuits as described herein. Rather, the example embodiment can be implemented and utilized in connection with many other applications.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

This written description uses examples to disclose the embodiments, including the best mode, and also to enable any person skilled in the art to practice the embodiments, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A static transfer switch comprising:
a first switch between a first voltage source and a load;
a second switch between a second voltage source and the load,
wherein the first switch and the second switch are configured to alternate power to the load between the first voltage source or the second voltage source; and
a rapid turn-off (RTO) system coupled across the first and second switches, the RTO system comprising:
a first RTO unit coupled in parallel with the first switch;
a second RTO unit coupled in parallel with the second switch; and
a first switched path connected between the first RTO unit and the second switch.

2. The static transfer switch of claim 1, wherein the first switched path comprises a first auxiliary switch.

3. The static transfer switch of claim 2, wherein the first auxiliary switch is closed when the second RTO unit fails such that the first RTO unit is configured to force commutation of the second switch during a voltage source transfer from the second voltage source to the first voltage source.

4. The static transfer switch of claim 1, wherein the RTO system further comprises a second switched path connected between the second RTO unit and the first switch.

5. The static transfer switch of claim 4, wherein the second switched path comprises a second auxiliary switch.

6. The static transfer switch of claim 5, wherein the second auxiliary switch is closed when the first RTO unit fails such that the second RTO unit is configured to force commutation of the first switch during a voltage source transfer from the first voltage source to the second voltage source.

7. The static transfer switch of claim 4, wherein the first and second RTO units share current from one of the first voltage source or the second voltage source to the load via the first and second switched paths.

8. The static transfer switch of claim 1, wherein the first switch is a first thyristor switch, and the second switch is a second thyristor switch.

9. A method for redundant rapid turn-off (RTO) unit switching within a static transfer switch (STS), the method comprising:
coupling a first switch between a first voltage source and a load;
coupling a second switch between a second voltage source and the load, wherein the first switch and the second switch are configured to alternate power to the load between the first voltage source or the second voltage source;
coupling an RTO system across the first and second switches, comprising:
coupling a first RTO unit in parallel with the first switch;
coupling a second RTO unit in parallel with the second switch; and
connecting a first switched path between the first RTO unit and the second switch; and
activating the first RTO unit to force commutation of the second switch during a voltage source transfer from the second voltage source to the first voltage source.

10. The method of claim 9, wherein said activating the first RTO unit comprises closing a first auxiliary switch along the first switched path.

11. The method of claim 9, wherein said coupling the RTO system across the first and second switches further comprises:
connecting a second switched path between the second RTO unit and the first switch.

12. The method of claim 11, further comprising activating the second RTO unit to force commutation of the first switch during a voltage source transfer from the first voltage source to the second voltage source.

13. The method of claim 12, wherein said activating the second RTO unit comprises closing a second auxiliary switch along the second switched path.

14. The method of claim 11, wherein the first switched path includes a first auxiliary switch, and the second switched path includes a second auxiliary switch, the method further comprising:
closing the first and second auxiliary switches to enable current sharing between the first RTO unit and the second RTO unit while the first voltage source or the second voltage source is powering the load.
